(19) United States
(12) Patent Application Publication
(10) Pub. No.: US 2023/0383184 A1
(43) Pub. Date: Nov. 30, 2023

(54) ETCHANT COMPOSITION

(71) Applicant: TOKYO OHKA KOGYO CO., LTD., Kawasaki-shi (JP)

(72) Inventors: Yuan-Chia Chang, Kawasaki-shi (JP); Po Ting Chou, Kawasaki-shi (JP); Ming-Yen Chung, Kawasaki-shi (JP)

(21) Appl. No.: 18/320,080

(22) Filed: May 18, 2023

(30) Foreign Application Priority Data
May 25, 2022 (TW) 111119483

(51) Int. Cl. C09K 13/00

(52) U.S. Cl. CPC C09K 13/00

(57) ABSTRACT

An etchant composition including an oxidizing agent, an organic tertiary amine or quaternary amine represented by the following Formula (1) or Formula (2), a basic compound, and a solvent, the etchant composition having a pH value of 7 or higher.

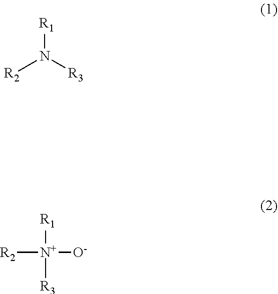

In Formula (1) and Formula (2), R₁ and R₂ each independently represents an alkyl group having 1 to 4 carbon atoms or a group represented by —(C₂H₄O)ₙH, where n represents 1 or 2, and R₁ and R₂ may be bonded to each other to form a nitrogen-containing heterocyclic ring together with the nitrogen atom; and R₃ represents a linear alkyl group having 4 to 18 carbon atoms, which may be substituted with a hydroxy group or an amino group at a terminal, and a methylene group included in the linear alkyl group may be substituted with an oxygen atom.

### BACKGROUND OF THE INVENTION

### Field of the Invention

The present invention relates to an etchant composition.

Priority is claimed on Taiwanese Patent Application No. 111119483, filed in Taiwan on May 25, 2022, the content of which is incorporated herein by reference.

### Description of Related Art

Various materials are used in semiconductor devices, and titanium nitride (TiN) films formed by various chemical vapor phase deposition methods (hereinafter, CVD methods) and silicon (Si) films formed by various CVD methods are used. A semiconductor element manufacturing process has etching steps, which include a step of selectively removing a certain material with respect to other materials.

For instance, when TiN is etched, it may be necessary to remove titanium nitride at the bottom by reducing lateral etching of titanium nitride in a limited area. However, commercially available SC-1 solution (a mixed solution of ammonium hydroxide (NH₄OH), hydrogen peroxide (H₂O₂), and water (H₂O)), which has been conventionally used to etch titanium nitride has a problem of over-etching into titanium nitride.

As examples of compositions for etching titanium nitride, Patent Document 1 discloses a composition for selectively removing PVD titanium nitride from a semiconductor device including PVD titanium nitride and a second material (selected from the group consisting of Cu, Co, CVD titanium nitride, a dielectric material, a low-k dielectric material, and combinations thereof), Patent Document 2 discloses an etching composition capable of selectively etching titanium nitride by preventing etching of a mask film or an organic film, and Patent Document 3 discloses an aqueous washing composition for washing a hard mask from a microelectronic device having a hard mask material (for example, titanium nitride).

### DOCUMENTS OF RELATED ART

[Patent Document 1] Taiwanese Patent No. 1616516
[Patent Document 2] United States Patent Application, Publication No. 2021238478
[Patent Document 3] Taiwanese Patent No. 1428442

### SUMMARY OF THE INVENTION

However, although compositions such as those described in Patent Documents 1 to 3 are capable of etching titanium nitride with high selectivity, etching of titanium nitride in a limited area, particularly lateral etching of titanium nitride, cannot be suppressed.

The present invention was achieved in view of the problems described above, and it is an object of the present invention to provide an etchant composition capable of suppressing lateral etching of titanium nitride in a limited area.

The inventors of the present invention have repeatedly conducted intensive studies to solve the above-described problems, and as a result, the inventors found that when etching into titanium nitride is performed with an etchant composition including a specific organic tertiary amine or quaternary amine having a bulky structure, the above-mentioned organic tertiary amine or quaternary amine adsorbs to the surface of TiO²⁺ to form a transient complex, and thereby lateral etching can be reduced, thus completing the present invention. The present invention specifically provides the following.

<1> An etchant composition including:
an oxidizing agent;
an organic tertiary amine or quaternary amine represented by the following Formula (1) or Formula (2);
a basic compound; and
a solvent,
in which the etchant composition has a pH value of 7 or higher:

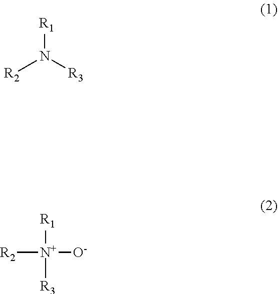

in Formula (1) and Formula (2), R₁ and R₂ each independently represent an alkyl group having 1 to 4 carbon atoms or a group represented by —(C₂H₄O)ₙH, where n represents 1 or 2, and R₁ and R₂ may be bonded to each other to form a nitrogen-containing heterocyclic ring together with the nitrogen atom; and R₃ represents a linear alkyl group having 4 to 18 carbon atoms, which may be substituted with a hydroxy group or an amino group at a terminal, and a methylene group included in the linear alkyl group may be substituted with an oxygen atom.

<2> The etchant composition according to the above item <1>, in which the oxidizing agent is hydrogen peroxide.

<3> The etchant composition according to the above item <1>, in which the organic tertiary amine or quaternary amine is at least one selected from the group consisting of bis(2-morpholinoethyl) ether, coconut amine ethoxylate, tributylamine, lauryldimethylamine oxide, tallow amine ethoxylate, N-lauryldiethanolamine, and stearyldiethanolamine.

<4> The etchant composition according to the above item <1>, in which the basic compound is at least one selected from the group consisting of ammonium hydroxide, potassium hydroxide, sodium hydroxide, and tetramethylammonium hydroxide (TMAH).

<5> The etchant composition according to the above item <4>, in which the basic compound is ammonium hydroxide.

<6> The etchant composition according to the above item <1>, further including a chelating agent.

<7> The etchant composition according to the above item <6>, in which the chelating agent is at least one selected from the group consisting of ethylenediaminetetraacetic acid (EDTA), hydroxyethylidenediphosphonic acid (HEDP), diethylenetriaminepentaacetic acid (DTPA), and (1,2-cyclohexylenedinitrilo)tetraacetic acid (CDTA).

<8> The etchant composition according to the above item <6>, in which a content of the oxidizing agent is 10% to 20% by weight, a content of the organic tertiary amine or quaternary amine is 0.5% to 2% by weight, a content of the basic compound is 0.01% to 0.5% by weight, and a content of the chelating agent is 0.01% to 0.5% by weight.

According to the present invention, an etchant composition capable of suppressing lateral etching of titanium nitride (TiN) in a limited area while maintaining a satisfactory rate of etching into titanium nitride can be provided.

### DETAILED DESCRIPTION OF THE INVENTION

<<Etchant Composition>>

The etchant composition of the present invention includes an oxidizing agent, an organic tertiary amine or quaternary amine represented by the following Formula (1) or Formula (2), a basic compound, and a solvent, and has a pH value of 7 or higher. The essential or optional components included in the etchant composition will be described below.

<Oxidizing Agent>

The oxidizing agent included in the etchant composition of the present invention is not particularly limited as long as it can oxidize titanium nitride. Examples include hydrogen peroxide, peracetic acid, perbenzoic acid, m-chloroperbenzoic acid, a percarbonic acid salt, urea peroxide, and perchloric acid; a perchloric acid salt; and persulfuric acid salts such as sodium persulfate, potassium persulfate, and ammonium persulfate, and among them, hydrogen peroxide is particularly preferred. The oxidizing agents may be used singly, or two or more kinds thereof may be used in combination.

The content of the oxidizing agent in the etchant composition of the present invention is preferably 7% to 25% by weight, and more preferably 10% to 20% by weight. When the content is within the above-described range, the rate of etching into titanium nitride is maintained at an appropriate level, and at the same time, over-etching into titanium nitride does not occur.

<Organic Tertiary Amine or Quaternary Amine Represented by Formula (1) or Formula (2)>

The etchant composition of the present invention can suppress over-etching into titanium nitride by including a specific organic tertiary amine or quaternary amine having a bulky structure.

Although the mechanism of action is not clear, it is believed that as the organic tertiary amine or quaternary amine adsorbs to the surface of TiO²⁺ formed from an oxidizing agent and titanium nitride to form a transient complex and suppresses further action of the oxidizing agent, lateral etching of titanium nitride can be reduced.

The organic tertiary amine or quaternary amine is represented by the following Formula (1) or Formula (2).

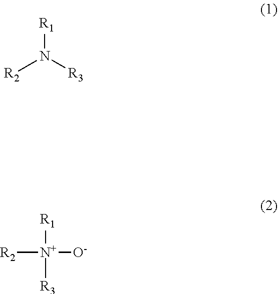

In Formula (1) and Formula (2), R₁ and R₂ each independently represent an alkyl group having 1 to 4 carbon atoms or a group represented by —(C₂H₄O)ₙH, where n represents 1 or 2, and R₁ and R₂ may be bonded to each other to form a nitrogen-containing heterocyclic ring together with the nitrogen atom; and R₃ represents a linear alkyl group having 4 to 18 carbon atoms, which may be substituted with a hydroxy group or an amino group at the terminal, and a methylene group included in the linear alkyl group may be substituted with an oxygen atom.

Examples of the alkyl group having 1 to 4 carbon atoms include a methyl group, an ethyl group, an n-propyl group, an isopropyl group, an n-butyl group, an isobutyl group, a sec-butyl group, and a tert-butyl group.

The number of carbon atoms in the nitrogen-containing heterocyclic ring is not particularly limited but is preferably 1 to 6, and specific examples include piperidino, morpholino, pyrrolidino, hexahydroazepino, and piperazino, among which morpholino is particularly preferred.

Examples of the linear alkyl group having 4 to 18 carbon atoms include an n-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, and an n-octadecyl group.

The number of carbon atoms in the amino group that can be substituted at the ends of the linear alkyl group having 4 to 18 carbon atoms is not particularly limited but is preferably 1 to 6, and the amino group may be any of a linear group, a branched group, or a cyclic group, among which a cyclic amino group is preferred. Specific examples of the cyclic amino group include a piperidino group, a morpholino group, a pyrrolidino group, a hexahydroazepino group, and a piperazino group, and among them, a morpholino group is particularly preferred.

Examples of the organic tertiary amine or quaternary amine represented by Formula (1) or Formula (2) used in the present invention include bis(2-morpholinoethyl) ether, coconut amine ethoxylate, tributylamine, lauryldimethylamine oxide, tallow amine ethoxylate, N-lauryldiethanolamine, and stearyldiethanolamine. The organic tertiary amines or quaternary amines represented by Formula (1) or Formula (2) may be used singly, or two or more kinds thereof may be used in combination.

The content of the organic tertiary amine or quaternary amine represented by Formula (1) or Formula (2) in the etchant composition of the present invention is preferably 0.01% to 5% by weight, and more preferably 0.1% to 2% by weight. When the content is within this range, further action of the oxidizing agent can be effectively suppressed, and lateral etching of titanium nitride can be reduced.

<Basic Compound>

The basic compound included in the etchant composition of the present invention is not particularly limited as long as it can decompose the oxide layer formed by a reaction between the oxidizing agent and titanium nitride. Preferably, the basic compound is at least one selected from the group consisting of a quaternary ammonium salt and an inorganic base, and examples include ammonium hydroxide, potassium hydroxide, sodium hydroxide, and tetramethylammonium hydroxide (TMAH), among which ammonium hydroxide is particularly preferred. The basic compounds may be used singly, two or more kinds thereof may be used in combination.

The content of the basic compound in the etchant composition of the present invention is preferably 0.01% to 0.5% by weight. When the content is within such a range, the rate of etching into titanium nitride is maintained at an appropriate level, and at the same time, over-etching into titanium nitride does not occur.

<Solvent>

The solvent used in the etchant composition of the present invention is not particularly limited as long as it can uniformly dissolve each component included in the composition. Any of water, an organic solvent, and an aqueous solution of an organic solvent can be used.

Specific examples of the organic solvent that can be used as the solvent include methyl ethyl ketone, acetone, methyl isobutyl ketone, diethyl ketone, cyclohexanone, ethylene glycol methyl ether, ethylene glycol ethyl ether, ethylene glycol butyl ether, ethylene glycol phenyl ether, diethylene glycol ethyl ether, diethylene glycol butyl ether, propylene glycol methyl ether, propylene glycol ethyl ether, dipropylene glycol methyl ether, dipropylene glycol ethyl ether, 3-methoxybutyl acetate, 4-methoxybutyl acetate, 2-methyl-3-methoxybutyl acetate, 3-methyl-3-methoxybutyl acetate, 3-ethyl-3-methoxybutyl acetate, 2-ethoxybutyl acetate, diethylene glycol ethyl ether acetate, and diethylene glycol butyl ether acetate, and among them, dipropylene glycol methyl ether (DPM) is preferred.

<Chelating Agent>

The etchant composition of the present invention preferably further includes a chelating agent in order to improve stability of the oxidizing agent, and extend the service life of the etchant composition.

The chelating agent included in the etchant composition of the present invention is not particularly limited; however, examples include ethylenediaminetetraacetic acid (EDTA), hydroxyethylidenediphosphonic acid (HEDP), diethylenetriaminepentaacetic acid (DTPA), and (1,2-cyclohexylenedinitrilo)tetraacetic acid (CDTA). The chelating agents may be used singly, or two or more kinds thereof may be used in combination.

The content of the chelating agent in the etchant composition of the present invention is preferably 0.01% to 0.5% by weight. When the content is within this range, an etchant composition including an oxidizing agent can be stabilized, and the service life of the composition can be extended.

<Other Components>

The etchant composition may include, in addition to the above-described components, various additives to the extent that the purpose of the present invention is not impaired. Examples of the additives include an oxidation inhibitor, an ultraviolet absorber, a surfactant, a pH adjusting agent, and a metal corrosion inhibitor.

<pH>

In the present invention, the pH of the etchant composition is adjusted to 7 or higher, and preferably to 8 or higher and 9 or lower. When the pH of the etchant composition is within the above-described range, the rate of etching into titanium nitride can be maintained.

<<Method for Preparing Etchant Composition>>

The etchant composition of the present invention is prepared by mixing the oxidizing agent, the organic tertiary amine or quaternary amine represented by Formula (1) or Formula (2), the basic compound, and the solvent described above, and a chelating agent or other components, which are added as necessary, and adjusting the pH in the range of 7 or higher. The mixing method is not particularly limited; however, for example, each component constituting the etchant composition may be mixed using a well-known mixing apparatus such as a blade agitator, an ultrasonic dispersing machine, or a homomixer.

<<Etching Method>>

The etchant composition described above is suitable for removing titanium nitride at the bottom by reducing lateral etching of titanium nitride in a limited area. Specifically, the etchant composition of the present invention can adequately remove titanium nitride at the bottom by, for example, bringing the etchant composition into contact with titanium nitride in a limited area at a temperature in the range of 50° C. to 60° C. by a spraying method, a dipping method, a spin coating method, a slit coating method, a roller coating method, or the like for about 0.5 to 10 minutes, and preferably about 1 to 5 minutes.

### EXAMPLES

Hereinafter, the present invention will be described in more detail by way of Examples; however, the present invention is not intended to be limited to these Examples.

### Reference Example, Examples 1 to 21, and Comparative Examples 1 to 4

An etchant composition was prepared by mixing each component of the type and content shown in Tables 1 and 2, with the balance being water, such that the total mass of the composition as a whole was 100% by weight. Furthermore, the unit of a numerical value representing the content of each component is % by weight.

The abbreviations shown in Tables 1 and 2 are as follows.
NE-240: Represented by the following structure.

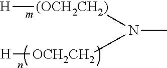

CCS-80: Polyoxyethylene coconut alkylamine
TETA: Triethylenetetramine
MDEA: N-methyldiethanolamine
HEDP: Hydroxyethylidene diphosphonic acid
DPM: Dipropylene glycol methyl ether

<Evaluation of Rate of Etching of Titanium Nitride (TiN)>

As an object to be etched, a test specimen cut to a size of 1 cm×1 cm from a silicon substrate having a TiN film with a film thickness of 500 Å formed on the surface by a CVD method was used. The test specimen was immersed in each of the etchant compositions described in Tables 1 and 2, which had been heated to 50° C., and the immersion time was 3 to 5 minutes (the immersion time was adjusted according to the rate of etching by each of the etchant compositions). Next, the test specimen was taken out and immersed in 500 mL of water, and the etchant composition adhering to the test specimen was removed. Thereafter, water remaining on the surface was removed by blowing dry nitrogen gas. The film thicknesses of titanium nitride (TiN) before and after immersion in the etchant composition were measured by X-ray fluorescence (XRF), and the rate of etching of titanium nitride (TiN) by the etchant composition was calculated from the change in the film thickness and the immersion time.

<Evaluation of Lateral Etching of Titanium Nitride (TiN)>

Structure 1 having a specific structure was used as a sample. The sample was immersed in each of the etchant compositions described in Tables 1 and 2, which had been heated to 50° C., and the immersion time was 0.5 to 2 minutes (the immersion time was adjusted according to the rate of etching by each of the etchant compositions). Next, the sample was then taken out and immersed in 500 mL of water, and the etchant composition adhering to the sample was removed. Thereafter, water remaining on the surface was removed by blowing dry nitrogen gas. Transmission electron microscope (TEM) was used to observe the surface of the etched sample, and the degree of lateral etching of titanium nitride (TiN) was evaluated.

Structure 1 had a structure in which a TiN film with a film thickness of about 3 nm was formed on a substrate, and a bottom anti-reflection coating (BARC) was formed on the TiN film as a patterned mask. Furthermore, the portion of TiN not covered by the BARC was etched first, and lateral etching occurred under the BARC.

TABLE 1

| | | Reference | Example | | | | | | | | |
|---|---|---|---|---|---|---|---|---|---|---|---|
| | | Example | 1 | 2 | 3 | 4 | 5 | 6 | 7 | 8 | 9 |
| Oxidizing | Hydrogen | 5.49 | 23.25 | 23.25 | 23.25 | 23.25 | 23.25 | 23.25 | 23.25 | 15.5 | 15.5 |
| agent | peroxide | | | | | | | | | | |
| Basic | Ammonium hydroxide | 0.82 | — | 0.03 | 0.01 | 0.05 | 0.01 | — | 0.05 | 0.15 | 0.15 |
| compound | Potassium hydroxide | — | — | — | — | — | — | — | — | — | — |
| | Sodium hydroxide | — | — | — | — | — | — | — | — | — | — |
| | Tetramethylammonium | — | — | — | — | — | — | — | — | — | — |
| | hydroxide | | | | | | | | | | |
| Organic | Bis(2-morpholinoethyl) | — | 1 | — | 1.25 | — | 1.25 | — | — | — | — |
| amine | ether | | | | | | | | | | |
| compound | Lauryldimethylamine | — | — | 1.25 | — | 1.25 | — | — | 0.05 | 0.013 | — |
| | oxide | | | | | | | | | | |
| | NE-240 | — | — | — | — | — | — | 2.5 | — | — | 4 |
| | CCS-80 | — | — | — | — | — | — | — | — | — | — |
| | Tallow amine ethoxylate | — | — | — | — | — | — | — | — | — | — |
| | Tributylamine | — | — | — | — | — | — | — | — | — | — |
| | Stearyldiethanolamine | — | — | — | — | — | — | — | — | — | — |
| | N-lauryldiethanolamine | — | — | — | — | — | — | — | — | — | — |
| | TETA | — | — | — | — | — | — | — | — | — | — |
| | MDEA | — | — | — | — | — | — | — | — | — | — |
| Chelating | HEDP | — | — | — | — | — | — | 0.05 | 0.05 | 0.05 | 0.05 |
| agent | | | | | | | | | | | |
| Solvent | DPM | — | — | — | — | — | — | — | — | — | — |
| | Water | Balance | Balance | Balance | Balance | Balance | Balance | Balance | Balance | Balance | Balance |

| | | | | | | | | | | |
|---|---|---|---|---|---|---|---|---|---|---|
| pH value | 10.3 | 7.5 | 7.2 | 7.4 | 7.4 | 7.4 | 9 | 7.6 | 8.7 | 8.7 |
| Rate of etching (Å/min) of | 67.8 | 30.9 | 71.1 | 69 | 112.8 | 70 | 76.9 | 141 | 160.2 | 98.8 |
| titanium nitride (TiN) | | | | | | | | | | |
| Lateral etching (nm) of | 98.8 | 4.8 | 7.8 | 5.4 | 4.8 | 4.2 | 4.2 | 4.2 | 4.2 | 7.2 |
| titanium nitride (TiN) | | | | | | | | | | |

| | | Example | | | | | | | | | |
|---|---|---|---|---|---|---|---|---|---|---|---|
| | | 10 | 11 | 12 | 13 | 14 | 15 | 16 | 17 | 18 | 19 |
| Oxidizing | Hydrogen | 15.5 | 15.5 | 15.5 | 15.5 | 15.5 | 15.5 | 7.75 | 7.75 | 15.5 | 15.5 |
| agent | peroxide | | | | | | | | | | |
| Basic | Ammonium hydroxide | 0.15 | — | — | — | 0.15 | 0.15 | 0.4 | 0.4 | 0.15 | 0.15 |
| compound | Potassium hydroxide | — | 0.15 | — | — | — | — | — | — | — | — |
| | Sodium hydroxide | — | — | 0.15 | — | — | — | — | — | — | — |
| | Tetramethylammonium | — | — | — | 0.15 | — | — | — | — | — | — |
| | hydroxide | | | | | | | | | | |
| Organic | Bis(2-morpholinoethyl) | 2 | 1.25 | 1.25 | 1.25 | 0.45 | 1.25 | — | — | — | — |
| amine | ether | | | | | | | | | | |
| compound | Lauryldimethylamine | — | — | — | — | — | — | 0.013 | 0.025 | — | — |
| | oxide | | | | | | | | | | |
| | NE-240 | — | — | — | — | — | — | — | — | — | — |
| | CCS-80 | — | — | — | — | 0.45 | 0.45 | — | — | — | — |
| | Tallow amine ethoxylate | — | — | — | — | — | — | — | — | 1.25 | — |
| | Tributylamine | — | — | — | — | — | — | — | — | — | 1.25 |
| | Stearyldiethanolamine | — | — | — | — | — | — | — | — | — | — |
| | N-lauryldiethanolamine | — | — | — | — | — | — | — | — | — | — |
| | TETA | — | — | — | — | — | — | — | — | — | — |
| | MDEA | — | — | — | — | — | — | — | — | — | — |
| Chelating | HEDP | 0.05 | 0.05 | 0.05 | 0.05 | 0.05 | 0.05 | 0.05 | 0.05 | 0.05 | 0.05 |
| agent | | | | | | | | | | | |
| Solvent | DPM | — | — | — | — | — | — | — | — | — | 10 |
| | Water | Balance | Balance | Balance | Balance | Balance | Balance | Balance | Balance | Balance | Balance |

| | | | | | | | | | | |
|---|---|---|---|---|---|---|---|---|---|---|
| pH value | 8.9 | 8.3 | 8.4 | 8 | 8.4 | 8.5 | 9.5 | 9.6 | 8.7 | 8.7 |
| Rate of etching (Å/min) of | 140.7 | 84.9 | 84.3 | 20.1 | 160.2 | 150.3 | 96 | 95.4 | 141.5 | 233.2 |
| titanium nitride (TiN) | | | | | | | | | | |
| Lateral etching (nm) of | 5 | 8 | 8 | 7.5 | 4.8 | 3.6 | 8.5 | 9.2 | 6.4 | 7.5 |
| titanium nitride (TiN) | | | | | | | | | | |

TABLE 2

| | | Example | | Comparative Example | | | |
|---|---|---|---|---|---|---|---|
| | | 20 | 21 | 1 | 2 | 3 | 4 |
| Oxidizing agent | Hydrogen peroxide | 15.5 | 15.5 | 23.25 | 23.25 | 23.25 | 15.5 |
| Basic compound | Ammonium hydroxide | 0.15 | 0.15 | — | — | — | 0.15 |
| | Potassium hydroxide | — | — | — | — | — | — |
| | Sodium hydroxide | — | — | — | — | — | — |
| | Tetramethylammonium | — | — | — | — | — | — |
| | hydroxide | — | — | — | — | — | — |
| Organic amine | Bis(2-morpholinoethyl) ether | — | — | — | — | — | — |
| compound | Lauryldimethylamine oxide | — | — | — | — | 0.38 | — |
| | NE-240 | — | — | — | — | — | — |
| | CCS-80 | — | — | — | — | — | — |
| | Tallow amine ethoxylate | — | — | — | — | — | — |
| | Tributylamine | — | — | — | — | — | — |
| | Stearyldiethanolamine | 0.1 | — | — | — | — | — |
| | N-lauryldiethanolamine | — | 1.25 | — | — | — | — |
| | TETA | — | — | 1.25 | — | — | — |
| | MDEA | — | — | — | 1.25 | — | — |
| Chelating agent | HEDP | 0.05 | 0.05 | — | — | — | 0.05 |
| Solvent | DPM | 20 | 20 | — | — | — | — |
| | Water | Balance | Balance | Balance | Balance | Balance | Balance |

| | | | | | | |
|---|---|---|---|---|---|---|
| pH value | 8.3 | 8.7 | 8.5 | 7.8 | 5.8 | 8.2 |
| Rate of etching (Å/min) of titanium nitride (TiN) | 185.3 | 187.7 | 25.7 | 30.7 | 13.1 | 154.2 |
| Lateral etching (nm) of titanium nitride (TiN) | 7 | 7 | 15.6 | 12 | 8.4 | 10 |

From Examples 1 to 21, it was verified that in the case of an etchant composition including an organic tertiary amine or quaternary amine represented by Formula (1) or Formula (2) and having a pH value of 7 or higher, the etchant composition can suppress lateral etching of titanium nitride while maintaining a satisfactory rate of etching into titanium nitride (TiN). On the other hand, from Comparative Examples 1 to 2 and 4, it was verified that when an etchant composition including no organic tertiary amine or quaternary amine represented by Formula (1) or Formula (2) is used, a certain rate of etching into titanium nitride (TiN) can be maintained; however, there is a problem of lateral over-etching. Furthermore, from Comparative Example 3, it was verified that when the pH value of the etchant composition is lower than 7, the rate of etching of titanium nitride (TiN) is inferior.

### Examples 2-1 to 2-5

An etchant composition was prepared by mixing each component of the type and content shown in Table 3, with the balance being water, such that the total mass of the composition as a whole was 100% by weight. Furthermore, the unit of a numerical value representing the content of each component is % by weight.

The abbreviations shown in Table 3 are as follows.
HEDP: Hydroxyethylidene diphosphonic acid
EDTA: Ethylenediaminetetraacetic acid
DTPA: Diethylenetriaminepentaacetic acid
CDTA: (1,2-Cyclohexylenedinitrilo)tetraacetic acid

<Evaluation of Stability Over Time in Rate of Etching by Etchant Composition>

As an object to be etched, a test specimen cut to a size of 1 cm×1 cm from a silicon substrate having a TiN film with a film thickness of 500 Å formed on the surface by a CVD method was used. The test specimen was immersed in an open cup (container having an aspect ratio of about 9:7) containing each of the etchant compositions described in Table 3, which had been heated to 50° C., and the rate of etching into titanium nitride (TiN) for an immersion time of 3 to 5 minutes (the immersion time was adjusted according to the initial rate of etching and the rate of etching by each of the etchant compositions) was measured. Next, the open cup containing the etchant composition was continuously heated at 50° C., and the rate of etching into titanium nitride (TiN) by the etchant composition was measured for a heating time of 1 hour, 3 hours, or 6 hours (the immersion time for the test specimen was 3 to 5 minutes). Then, the stability over time in the rate of etching by the etchant composition was evaluated by dividing the rate of etching of titanium nitride (TiN) for a heating time of 1 hour, 3 hours, or 6 hours, by the initial rate of etching of each of the titanium nitride (TiN).

TABLE 3

| | | Example | | | | |
|---|---|---|---|---|---|---|
| | | 2-1 | 2-2 | 2-3 | 2-4 | 2-5 |
| Oxidizing | Hydrogen | 15.5 | 15.5 | 15.5 | 15.5 | 15.5 |
| agent | peroxide | | | | | |
| Basic | Ammonium | 0.15 | 0.15 | 0.15 | 0.15 | 0.15 |
| compound | hydroxide | | | | | |
| Organic | Bis(2- | 1.25 | 1.25 | 1.25 | 1.25 | 1.25 |
| amine | morpholinoethyl) | | | | | |
| compound | ether | | | | | |
| Chelating | HEDP | — | 0.05 | — | — | — |
| agent | EDTA | — | — | 0.05 | — | — |
| | DTPA | — | — | — | 0.05 | — |
| | CDTA | — | — | — | — | 0.05 |
| Solvent | Water | Balance | Balance | Balance | Balance | Balance |

| | | | | | |
|---|---|---|---|---|---|
| pH value | 8.9 | 8.7 | 8.7 | 8.7 | 8.7 |
| Initial rate of etching (Å/min) of | 153.7 | 144.5 | 146.2 | 137.3 | 154.3 |
| titanium nitride (TiN) | | | | | |
| Rate of etching after 1 hour/initial | 98.65% | 112.6% | 90.61% | 98.01% | 95.43% |
| rate of etching | | | | | |
| Rate of etching after 3 hour/initial | 87.39% | 102% | 87.12% | 90.16% | 96.84% |
| rate of etching | | | | | |
| Rate of etching after 6 hour/initial | 74.84% | 96% | 87.69% | 97.85% | 95.37% |
| rate of etching | | | | | |

From a comparison of Examples 2-1 to 2-5 in the above table, it could be verified that in Examples 2-2 to 2-5 in which the etchant composition of the present invention further includes a chelating agent, a constant rate of etching can be maintained even for after a long time period, that is, the service life of the etchant composition can be extended, as compared with Example 2-1, which does not include a chelating agent.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. An etchant composition comprising:
an oxidizing agent;
an organic tertiary amine or quaternary amine represented by the following Formula (1) or Formula (2);
a basic compound; and
a solvent,
wherein the etchant composition has a pH value of 7 or higher: 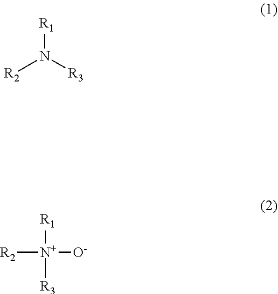
wherein in Formula (1) and Formula (2), R₁ and R₂ each independently represents an alkyl group having 1 to 4 carbon atoms or a group represented by —(C₂H₄O)ₙH, where n represents 1 or 2, and R₁ and R₂ may be bonded to each other to form a nitrogen-containing heterocyclic ring together with the nitrogen atom; and R₃ represents a linear alkyl group having 4 to 18 carbon atoms, which may be substituted with a hydroxy group or an amino group at a terminal, and a methylene group included in the linear alkyl group may be substituted with an oxygen atom.

2. The etchant composition according to claim 1, wherein the oxidizing agent is hydrogen peroxide.

3. The etchant composition according to claim 1, wherein the organic tertiary amine or quaternary amine is at least one selected from the group consisting of bis(2-morpholinoethyl) ether, coconut amine ethoxylate, tributylamine, lauryldimethylamine oxide, tallow amine ethoxylate, N-lauryldiethanolamine, and stearyldiethanolamine.

4. The etchant composition according to claim 1, wherein the basic compound is at least one selected from the group consisting of ammonium hydroxide, potassium hydroxide, sodium hydroxide, and tetramethylammonium hydroxide (TMAH).

5. The etchant composition according to claim 1, wherein the basic compound is ammonium hydroxide.

6. The etchant composition according to claim 1, further comprising a chelating agent.

7. The etchant composition according to claim 6, wherein the chelating agent is at least one selected from the group consisting of ethylenediaminetetraacetic acid (EDTA), hydroxyethylidenediphosphonic acid (HEDP), diethylenetriaminepentaacetic acid (DTPA), and (1,2-cyclohexylenedinitrilo)tetraacetic acid (CDTA).

8. The etchant composition according to claim 6, wherein a content of the oxidizing agent is 10% to 20% by weight, a content of the organic tertiary amine or quaternary amine is 0.5% to 2% by weight, a content of the basic compound is 0.01% to 0.5% by weight, and a content of the chelating agent is 0.01% to 0.5% by weight.
